(19) United States
(12) Patent Application Publication
(10) Pub. No.: US 2025/0126707 A1
(43) Pub. Date: Apr. 17, 2025

(54) PRINTED CIRCUIT BOARD

(71) Applicant: SAMSUNG ELECTRO-MECHANICS CO., LTD., Suwon-si (KR)

(72) Inventors: Sang Won HAN, Suwon-si (KR); Sang Ho JEONG, Suwon-si (KR); Chang Hwa PARK, Suwon-si (KR); Hyun Hu LEE, Suwon-si (KR); Deok Hong JO, Suwon-si (KR); Jong Eun PARK, Suwon-si (KR)

(73) Assignee: SAMSUNG ELECTRO-MECHANICS CO., LTD., Suwon-si (KR)

(21) Appl. No.: 18/829,690

(22) Filed: Sep. 10, 2024

(30) Foreign Application Priority Data
Oct. 17, 2023 (KR) 10-2023-0138232

(51) Int. Cl. H05K 1/02; H05K 1/09

(52) U.S. Cl. CPC H05K 1/0298; H05K 1/09; H05K 2201/0338

(57) ABSTRACT

A printed circuit board includes an insulating layer and a wiring pattern disposed on or within the insulating layer, wherein the wiring pattern includes a first metal layer, a second metal layer disposed on an upper surface of the first metal layer, and an inorganic oxide film disposed on a side surface of the second metal layer.

### CROSS-REFERENCE TO RELATED APPLICATIONS

This application claims benefit of priority to Korean Patent Application No. 10-2023-0138232 filed on Oct. 17, 2023 in the Korean Intellectual Property Office, the disclosure of which is incorporated herein by reference in its entirety.

### TECHNICAL FIELD

The present disclosure relates to a printed circuit board.

### BACKGROUND

As the production of high-performance printed circuit boards has been required, the implementation of microcircuits has become increasingly important. In order to implement microcircuits, it is necessary to secure uniform and fine lines L and space S. For example, in the case of high-end products, such as 2.nD, line L and space S each may be required to be on the scale of several micrometers. However, in the case of a related art microcircuit formation process, undercuts may occur below a microcircuit pattern when a seed layer is etched, which may lead to poor circuit reliability.

### SUMMARY

An aspect of the present disclosure is to provide a printed circuit board capable of preventing undercuts from occurring during, for example, an etching process, when a microcircuit is formed.

According to an aspect of the present disclosure, a printed circuit board includes an insulating layer and a wiring pattern disposed on or within the insulating layer, wherein the wiring pattern includes a first metal layer, a second metal layer disposed on an upper surface of the first metal layer, and an inorganic oxide film disposed on a side surface of the second metal layer.

According to another aspect of the present disclosure, a printed circuit board includes a substrate, a first metal layer disposed on the substrate, a second metal layer disposed on the first metal layer, and a barrier layer disposed to surround the second metal layer and having a protrusion at least partially protruding from a lower end of the barrier layer in a plane direction, perpendicular to a stacking direction.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating one embodiment of an electronic device;

FIG. 3 is a cross-sectional view schematically illustrating one embodiment of a printed circuit board;

FIGS. 4A, 4B, 4C, 4D, 4E, 4F, 4G, and 4H are cross-sectional views schematically illustrating an example of a manufacturing process of the printed circuit board of FIG. 3;

FIG. 5 is a cross-sectional view schematically illustrating another example of a printed circuit board;

FIGS. 6A, 6B, 6C, 6D, 6E, 6F, 6G, 6H, and 6I are cross-sectional views schematically illustrating an example of a manufacturing process of the printed circuit board of FIG. 5; and

FIGS. 7A and 7B are cross-sectional views illustrating the effect of etching depending on the presence or absence of an inorganic oxide film.

### DETAILED DESCRIPTION

Hereinafter, embodiments of the present disclosure will be described as follows with reference to the attached drawings.

### Electronic Device

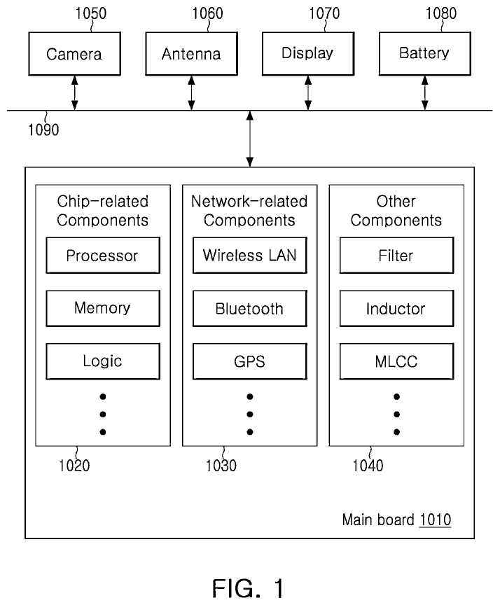

FIG. 1 is a schematic block diagram illustrating one embodiment of an electronic device system.

Referring to FIG. 1, an electronic device 1000 may accommodate a mainboard 1010. The mainboard 1010 may include chip related components 1020, network related components 1030, other components 1040, or the like, physically or electrically connected thereto. These components may be coupled to other electronic components to be described below to form various signal lines 1090.

The chip-related components 1020 may include a memory chip, such as a volatile memory (e.g., a dynamic random access memory (DRAM)), a non-volatile memory (e.g., a read only memory (ROM)), a flash memory, or the like; an application processor chip, such as a central processor (e.g., a central processing unit (CPU)), a graphics processor (e.g., a graphics processing unit (GPU)), a digital signal processor, a cryptographic processor, a microprocessor, a microcontroller, or the like; and a logic chip, such as an analog-to-digital converter, an application-specific integrated circuit (ASIC), or the like, or the like. However, the chip-related components 1020 are not limited thereto, and may include other types of chip-related components. In addition, the chip-associated components 1020 may be combined with each other. The chip-associated components 1020 may be in a package form including the aforementioned chips or electronic components.

The network-related components 1030 may include protocols, such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the abovementioned protocols. However, the network-related components 1030 are not limited thereto, but may also include a variety of other wireless or wired standards or protocols. In addition, the network-related components 1030 may be combined with each other, together with the chip-related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other electronic components that may or may not be physically or electrically connected to the mainboard 1010. These other components may include, for example, a camera 1050, an antenna 1060, a display 1070, a battery 1080. However, without being limited thereto, the electronic device 1000 may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. In addition, the electronic device 1000 may also include other components used for various purposes depending on a type of the electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device able to process data.

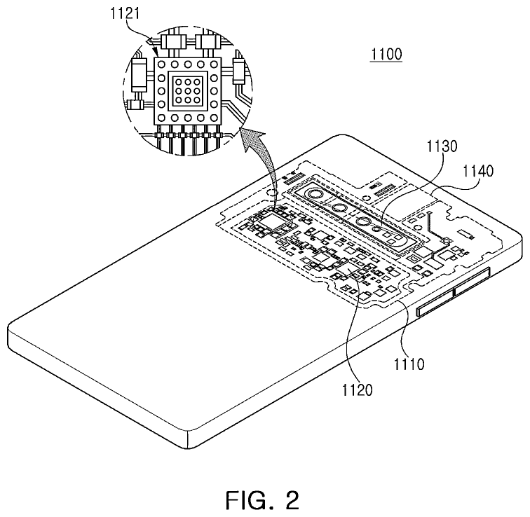

FIG. 2 is a perspective view schematically illustrating one embodiment of an electronic device.

Referring to FIG. 2, the electronic device may be, for example, a smartphone 1100. A motherboard 1110 may be accommodated in the smartphone 1100, and various electronic components 1120 may be physically and/or electrically connected to the motherboard 1110. In addition, other components that may or may not be physically or electrically connected to the printed circuit board (PCB) 1110, such as a camera module 1130 and/or a speaker 1140, may be accommodated in the motherboard 1110. Some of the components 1120 may be the chip-related components described above, for example, a component package 1121, but are not limited thereto. The component package 1121 may be in the form of a PCB on which electronic components including active components and/or passive components are surface-mounted. Alternatively, the component package 1121 may be in the form of a PCB with built-in active components and/or passive components. Meanwhile, the electronic device is not limited to the smartphone 1100, and of course may be other electronic devices as described above.

### PCB

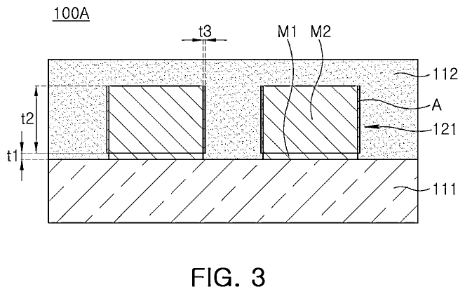

FIG. 3 is a cross-sectional view schematically illustrating one embodiment of a PCB.

Referring to FIG. 3, a PCB 100A according to one embodiment may include a first insulating layer 111, a first wiring pattern 121 disposed on an upper surface of the first insulating layer 111, and a second insulating layer 112 disposed on the upper surface of the first insulating layer 111 and covering at least a portion of the first wiring pattern 121. The first wiring pattern 121 may be disposed on the first insulating layer 111 and may be disposed within the second insulating layer 112. The first wiring pattern 121 may include a first metal layer M1, a second metal layer M2 disposed on an upper surface of the first metal layer M1, and an inorganic oxide film A disposed on a side surface of the second metal layer M2. The first wiring pattern 121 may be provided in plural, and the plurality of first wiring patterns 121 may be microcircuits in which a line L/space S is less than 10 μm/10 μm, for example, within 5 μm/5 μm, or within 2 μm/2 μm. The inorganic oxide film A may be a thin film having a thickness less than 100 nm. In this manner, when the first wiring pattern 121, which is a microcircuit, is formed, the occurrence of undercut may be prevented (to be described below) by disposing the thin inorganic oxide film A. Therefore, it may be easy to secure circuit adhesion and circuit stability. In addition, it may be easier to implement fine patterns.

Meanwhile, the first and second metal layers M1 and M2 may be differentiated layers formed separately from each other, and for example, the average grain sizes thereof may be different. Here, a thickness t2 of the second metal layer M2 may be greater than a thickness t1 of the first metal layer M1. In addition, the thickness t1 of the first metal layer M1 may be greater than a thickness t3 of the inorganic oxide film A. For example, the first metal layer M1 may be a seed layer formed by electroless plating, etc., and may include, for example, chemical copper. In addition, the second metal layer M2 may be a plating layer formed by electrolytic plating or the like and may include, for example, electrolytic copper. Accordingly, the thickness t2 of the second metal layer M2 may be greater than the thickness t1 of the first metal layer M1. In addition, the inorganic oxide film A may be formed to be very thin using a thin film deposition method. Accordingly, the thickness t3 of the inorganic oxide film A may be less than the thickness t1 of the first metal layer M1. The inorganic oxide film A may include a material to which atomic layer deposition (ALD) or molecular vapor deposition (MVD) is applicable, for example, at least one of Al₂O₃, TiO₂, ZnO, ZnO₂, ZrO₂, SnO, SnO₂, HfO₂, and SiO₂, but is not limited thereto. Meanwhile, when the inorganic oxide film A is formed using a thin film deposition method, such as ALD or MVD, uniformity, step coverage, and the like may be improved, compared to a case in which a protective film is formed with a different material by plasma deposition and the like.

Meanwhile, at least a portion of a side surface of the first metal layer M1 may be exposed from the inorganic oxide film A. For example, the inorganic oxide film A may be spaced apart from a portion of a side surface of the first metal layer M1. In one embodiment, the inorganic oxide film A may not cover the side surface of the first metal layer M1. In addition, the inorganic oxide film A may also be spaced apart from a portion of an upper surface of the second metal layer M2. In one embodiment, the inorganic oxide film A may not cover the upper surface of the second metal layer M2. For example, the inorganic oxide film A may be disposed only on the side surface of the second metal layer M2 or may be disposed to surround the second metal layer M2. The inorganic oxide film A may be conformally formed with a substantially constant thickness on the side surface of the second metal layer M2. Through this arrangement, the occurrence of undercuts in etching may be effectively prevented.

Hereinafter, components of the PCB 100A according to one embodiment re described in more detail with reference to the drawings.

The first and second insulating layers 111 and 112 may each include an insulating material. Insulating materials may include a thermosetting resin, such as an epoxy resin, a thermoplastic resin, such as polyimide, or materials including an inorganic filler, an organic filler and/or glass fiber (glass cloth or glass fabric) along with a resin. For example, the insulating material may be a non-photosensitive insulating material, such as copper clad laminate (CCL), Ajinomoto build-up film (ABF), or prepreg (PPG), but is not limited thereto, and other polymer materials may be used. In addition, the insulating material may be a photosensitive insulating material, such as photoimageable dielectric (PID). When the first and second insulating layers 111 and 112 include the same material, they may be integrated with each other to form one insulating layer, but without being limited thereto, the first and second insulating layers 111 and 112 may be differentiated layers. The first insulating layer 111 may be a substrate in a broader sense, and the substrate may have various materials, such as a glass substrate, a silicon substrate, and a ceramic substrate, in addition to the organic substrate described above.

The first wiring pattern 121 may include a metal material. For example, the first and second metal layers M1 and M2 may include copper (Cu), aluminum (Al), silver (Ag), tin (Sn), gold (Au), nickel (Ni), lead (Pb), titanium (Ti), and/or alloys thereof, etc. Preferably, the first and second metal layers M1 and M2 may each include copper (Cu), but are not limited thereto. The first wiring pattern 121 may be a signal pattern, and if necessary, a power pattern or a ground pattern may be further disposed on the same layer as the first wiring pattern 121. The first wiring pattern 121 may be a line pattern, and if necessary, a plain pattern or pad pattern may be further disposed on the same layer as the first wiring pattern 121. The first wiring pattern 121 may include multiple metal layers, for example, the first metal layer M1, an electroless plating layer (or chemical copper), and the second metal layer M2, an electrolytic plating layer (or electrolytic copper).

As described above, the inorganic oxide film A may be a thin film having a thickness less than 100 nm, for example, a thickness of about 1 nm to 10 nm. In addition, the inorganic oxide film A may include a material to which atomic layer deposition (ALD) or molecular vapor deposition (MVD) is applicable, for example, at least one of Al₂O₃, TiO₂, ZnO, ZnO₂, ZrO₂, SnO, SnO₂, HfO₂, and SiO₂, preferably, Al₂O₃, but is not limited thereto. The inorganic oxide film A may be used as a barrier layer to prevent undercut due to etching, and may also be used as an adhesive layer to improve adhesion to the second insulating layer 112.

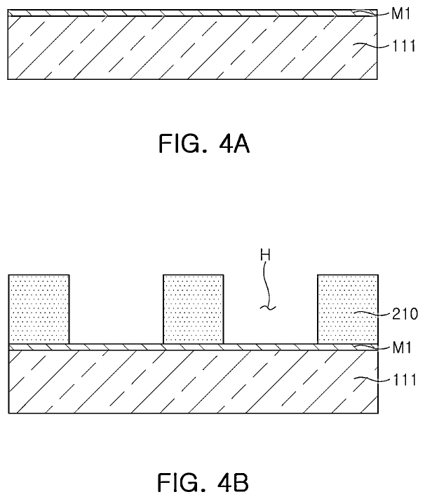

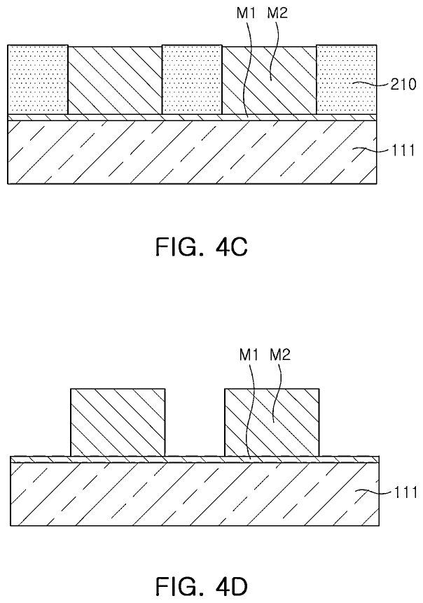

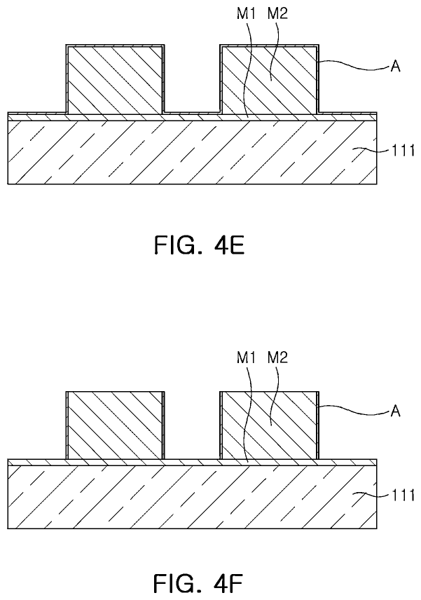

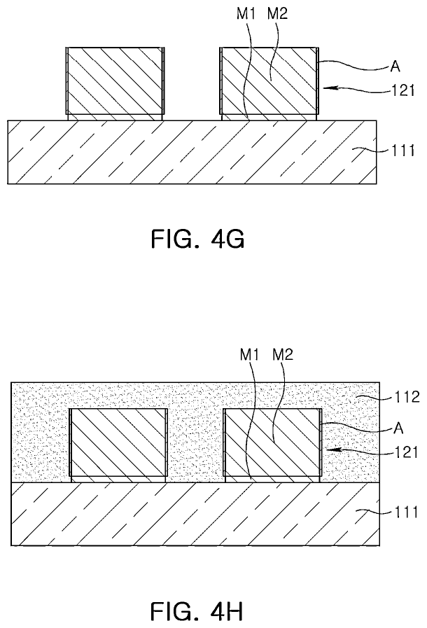

FIGS. 4A to 4H are cross-sectional views schematically illustrating an example of a manufacturing process of the PCB of FIG. 3.

Referring to FIG. 4A, the first metal layer M1 is formed on the first insulating layer 111 by electroless plating or the like. The first insulating layer 111 may be various types of substrates, such as an organic substrate, a glass substrate, a silicon substrate, or a ceramic substrate. The first metal layer M1 may include chemical copper. The first metal layer M1 may be a seed layer.

Referring to FIG. 4B, a resist layer 210 is formed on the first metal layer M1, and the resist layer 210 is exposed and developed through a photolithography process to form a patterned opening H exposing an upper surface of the first metal layer M1.

Referring to FIG. 4C, the second metal layer M2 is formed on the first metal layer M1 by electrolytic plating or the like to fill at least a portion of the patterned opening H. The second metal layer M2 may be a plating layer which substantially becomes a microcircuit.

Referring to FIG. 4D, the resist layer 210 is removed. The resist layer 210 may be chemically peeled using a stripper or may be physically peeled.

Referring to FIG. 4E, the inorganic oxide film A is formed on the first and second metal layers M1 and M2 to cover them. The inorganic oxide film A may be formed to be thin using a thin film deposition method, such as ALD or MVD.

Referring to FIG. 4F, the inorganic oxide film A disposed on the upper surface of each of the first and second metal layers M1 and M2 is removed using etching. For example, the inorganic oxide film A may remain only on the side surface of the second metal layer M2. Dry etching, such as plasma etching, may be used as etching, but is not limited thereto.

Referring to FIG. 4G, unnecessary first metal layer M1 in regions other than the region in which the second metal layer M2 is formed is removed. For example, the first metal layer M1 may remain only below the second metal layer M2. Wet etching, such as flash etching, may be used as etching, but is not limited thereto. During the etching process, the inorganic oxide film A may prevent undercuts from occurring at a lower end of the side surface of the second metal layer M2. Through a series of processes, the first wiring pattern 121, which is a microcircuit, may be formed.

Referring to FIG. 4H, the second insulating layer 112 is formed on the first insulating layer 111. The second insulating layer 112 may be formed through a lamination process. The first wiring pattern 121 may be embedded in the second insulating layer 112. The PCB 100A according to the example described above may be manufactured through a series of processes, and other redundant descriptions are omitted.

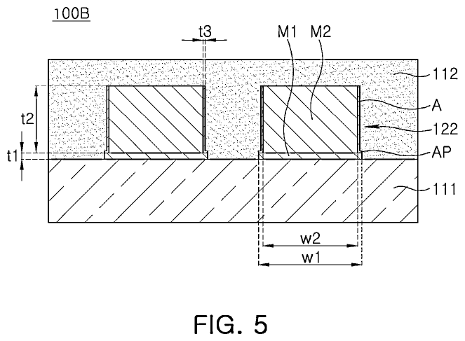

FIG. 5 is a cross-sectional view schematically illustrating another example of a PCB.

Referring to FIG. 5, in a PCB 100B according to another example, the second wiring pattern 122, instead of the first wiring pattern 121, may be disposed in the PCB 100A according to the example described above. In the cross-section of the second wiring pattern 122, a width w1 of the first metal layer M1 may be greater than a width w2 of the second metal layer M2. For example, in the second wiring pattern 122, the side surface of the first metal layer M1 may protrude, compared to the side surface of the second metal layer M2. Here, the second wiring pattern 122 may have a protrusion AP formed as at least a portion of the inorganic oxide film A protrudes in a plane direction, perpendicular to a stacking direction, from a lower end of the inorganic oxide film A. The protrusion AP may be formed to cover at least a portion of the upper surface of the first metal layer M1 but may be spaced apart from the side surface. For example, the inorganic oxide film A of the second wiring pattern 122 may extend to be disposed on the protruding region of the first metal layer M1. Also, in this case, the technical effect described above may be achieved, for example, the occurrence of undercut may be prevented by disposing the thin inorganic oxide film A when the second wiring pattern 122, which is a microcircuit, is formed. Therefore, it may be easy to secure circuit adhesion and circuit stability. In addition, it may be easier to implement fine patterns. Other contents are substantially the same as those described in the PCB according to the example described above, and thus, redundant descriptions are omitted.

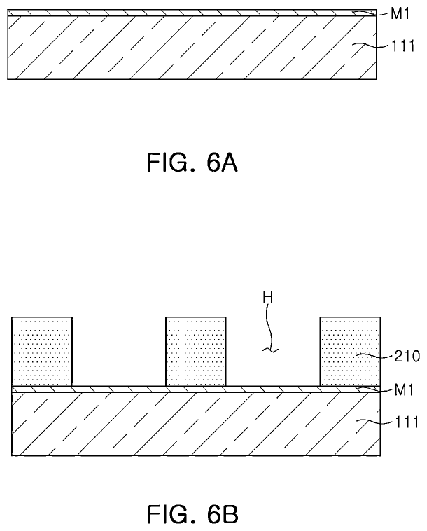

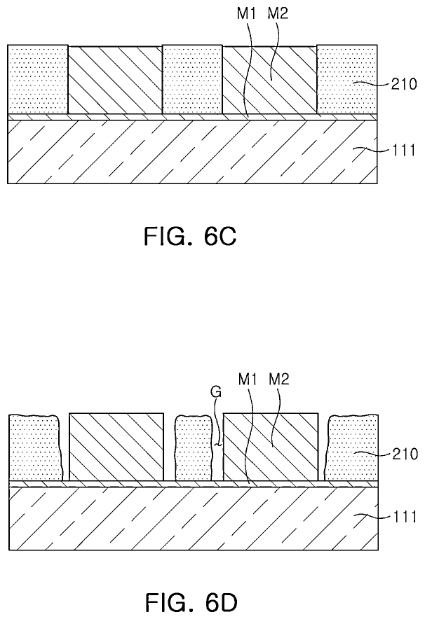

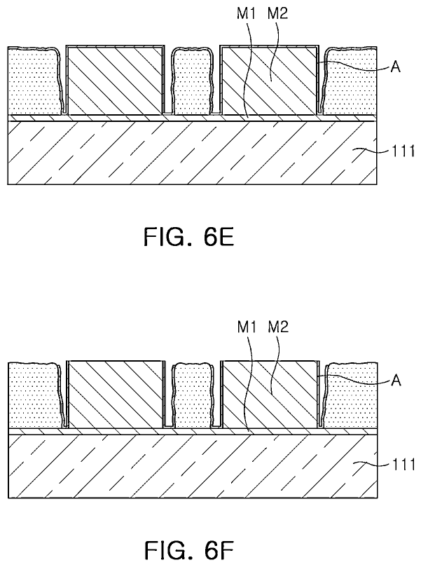

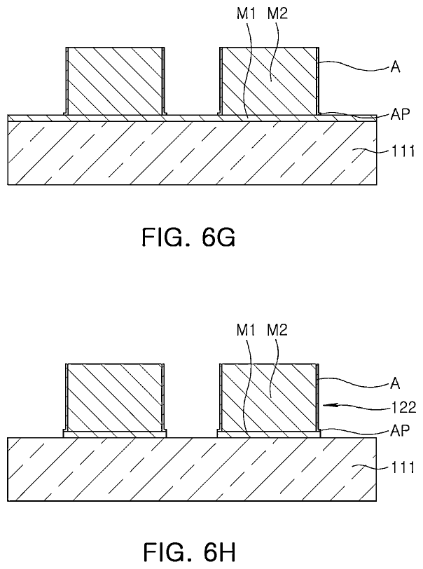

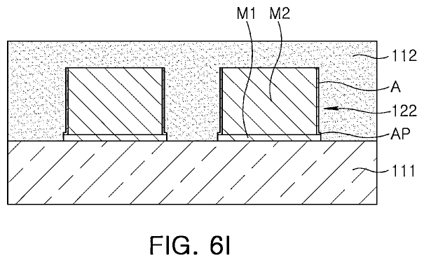

FIGS. 6A to 6I are cross-sectional views schematically illustrating an example of a manufacturing process of the PCB of FIG. 5.

Referring to FIG. 6A, the first metal layer M1 is formed on the first insulating layer 111 by electroless plating, etc. The first insulating layer 111 may be various types of substrates, such as an organic substrate, a glass substrate, a silicon substrate, or a ceramic substrate. The first metal layer M1 may include chemical copper. The first metal layer M1 may be a seed layer.

Referring to FIG. 6B, the resist layer 210 is formed on the first metal layer M1, and the resist layer 210 is exposed and developed through a photolithography process to form the patterned opening H exposing the upper surface of the first metal layer M1.

Referring to FIG. 6C, the second metal layer M2 is formed on the first metal layer M1 by electrolytic plating or the like to fill at least a portion of the patterned opening H. The second metal layer M2 may be a plating layer that substantially becomes a microcircuit.

Referring to FIG. 6D, a portion of the resist layer 210 is removed through soft peeling. A peeling liquid may be used for soft peeling. A space G may be formed between the second metal layer M2 and the resist layer 210 through soft peeling.

Referring to FIG. 6E, the inorganic oxide film A is formed on the first and second metal layers M1 and M2 and the resist layer 210 to cover them. The inorganic oxide film A may also be formed on the wall of the space G between the second metal layer M2 and the resist layer 210. The inorganic oxide film A may be formed to be thin using a thin film deposition method, such as ALD or MVD.

Referring to FIG. 6F, the inorganic oxide film A disposed on the upper surface of each of the second metal layer M2 and the resist layer 210 is removed using etching. For example, the inorganic oxide film A may remain only on the side surface of the second metal layer M2, on the wall of the space G between the second metal layer M2 and the resist layer 210, and on the upper surface of the first metal layer M1. Dry etching, such as plasma etching, may be used as etching, but is not limited thereto.

Referring to FIG. 6G, the resist layer 210 is removed. The resist layer 210 may be chemically peeled using a stripper or may be physically peeled. After the resist layer 210 is peeled off, the protrusion AP covering a portion of the upper surface of the first metal layer M1 may remain at the lower end of the inorganic oxide film A.

Referring to FIG. 6H, the unnecessary first metal layer M1 in regions other than the region in which the second metal layer M2 and the inorganic oxide film A are formed is removed using etching. For example, the first metal layer M1 may remain only below the second metal layer M2 and the inorganic oxide film A. Wet etching, such as flash etching, may be used as etching, but is not limited thereto. During the etching process, the inorganic oxide film A may prevent undercuts from occurring at a lower end of the side surface of the second metal layer M2. Through a series of processes, the second wiring pattern 122, which is a microcircuit, may be formed.

Referring to FIG. 6I, the second insulating layer 112 is formed on the first insulating layer 111. The second insulating layer 112 may be formed through a lamination process. The second wiring pattern 122 may be embedded in the second insulating layer 112. The PCB 100B according to another example described above may be manufactured through a series of processes, and other redundant descriptions are omitted.

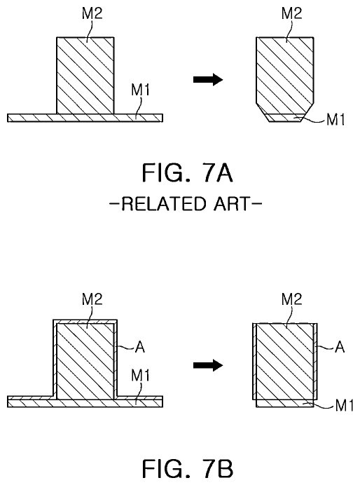

FIG. 7 is a cross-sectional view illustrating the effect of etching depending on the presence or absence of an inorganic oxide film.

Referring to FIG. 7, if there is no oxide film A as shown in FIG. 7A, an undercut may occur at the lower end of the second metal layer M2 during the etching process to remove the first metal layer M1. Meanwhile, in the case of forming the inorganic oxide film A as in FIG. 7B, the inorganic oxide film A may prevent an undercut from occurring at the lower end of the second metal layer M2 during the etching process to remove the first metal layer M1. Therefore, it may be easy to secure circuit adhesion and circuit stability. In addition, it may be easier to implement fine patterns.

As one of the various effects of the present disclosure, the PCB in which undercuts are prevented from occurring during, for example, an etching process when a microcircuit is formed.

In the present disclosure, the expression “covering” may include not only covering entirely but also covering at least portion, and may also include covering indirectly as well as covering directly. In addition, the expression “filling” may include not only completely filling but also at least partially filling, and may also include approximately filling. For example, this may include cases in which some air gaps or voids exist. In addition, the expression “surrounding” may include not only completely surrounding, but also partially surrounding and approximately surrounding. In addition, the expression “being adjacent to” refers to arrangement next to each other on substantially the same layer and is not limited to a case of being in contact with each other. In addition, exposing may include not only fully exposing but also partially exposing, and exposing may refer to exposing from burying a corresponding component.

In the present disclosure, determination may be made to include process errors, position deviations, errors during measurement, and the like that occur during a manufacturing process. For example, substantially being coplanar may include not only presence completely on the same plane, but also presence approximately on the same plane.

In the present disclosure, the same insulating material may refer to not only the exactly same insulating material but also the same type of insulating material. Accordingly, the composition of insulating materials may be substantially the same, but specific composition ratios thereof may vary slightly.

In the present disclosure, a cross-section may refer to a cross-sectional shape when an object is cut vertically, a cross-sectional shape when an object is cut vertically, or a cross-sectional shape when an object is viewed from a side view. In addition, “on a plane” may refer to a planar shape when an object is cut horizontally or a planar shape when an object is viewed from a top-view or bottom-view.

In the present disclosure, a lower side, a lower portion, a lower surface, and the like are used to refer to a downward direction based on a cross-section of a drawing for the sake of convenience, and an upper side, an upper portion, an upper surface, and the like are used to mean the opposite direction. However, this defines directions for convenience of description, and the scope of the claims is not particularly limited by the descriptions of the directions, and the concept of top/bottom may change at any time.

In the present disclosure, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” In addition, it may be understood that when an element is referred to with “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The expression “an exemplary embodiment or one example” used in the present disclosure does not refer to identical examples and is provided to stress different unique features between each of the examples. However, examples provided in the following description are not excluded from being associated with features of other examples and implemented thereafter. For example, even if matters described in a specific example are not described in a different example thereto, the matters may be understood as being related to the other example, unless otherwise mentioned in descriptions thereof.

The terms used herein are for the purpose of describing particular exemplary embodiments only and are not intended to limit the exemplary embodiments. As used herein, the singular forms “a”, “an” and “the” are intended to include the plural forms as well, unless the context clearly indicates otherwise.

What is claimed is:

1. A printed circuit board comprising:
an insulating layer; and
a wiring pattern disposed on or within the insulating layer,
wherein the wiring pattern includes a first metal layer, a second metal layer disposed on an upper surface of the first metal layer, and an inorganic oxide film disposed on a side surface of the second metal layer.

2. The printed circuit board of claim 1, wherein
the second metal layer is thicker than the first metal layer, and
the first metal layer is thicker than the inorganic oxide layer.

3. The printed circuit board of claim 1, wherein the inorganic oxide film has a thickness less than 100 nm.

4. The printed circuit board of claim 1, wherein the inorganic oxide film includes at least one of Al₂O₃, TiO₂, ZnO, ZnO₂, ZrO₂, SnO, SnO₂, HfO₂, or SiO₂.

5. The printed circuit board of claim 1, wherein at least a portion of a side surface of the first metal layer is exposed from the inorganic oxide film.

6. The printed circuit board of claim 5, wherein
the inorganic oxide film is spaced apart from a portion of the side surface of the first metal layer, and
the inorganic oxide film is spaced apart from a portion of the upper surface of the second metal layer.

7. The printed circuit board of claim 6, wherein
the inorganic oxide film does not cover the side surface of the first metal layer, and
the inorganic oxide film does not cover the upper surface of the second metal layer.

8. The printed circuit board of claim 1, wherein
a side surface of the first metal layer protrudes compared to the side surface of the second metal layer, and
the inorganic oxide film is disposed to extend onto a protruding region of the first metal layer.

9. The printed circuit board of claim 1, wherein
the inorganic oxide film disposed on the side surface of the second metal layer is bent to be disposed on a portion of an upper surface of the first metal layer at the protruding region.

10. The printed circuit board of claim 1, wherein the first and second metal layers have different average grain sizes.

11. The printed circuit board of claim 10, wherein
the first metal layer includes chemical copper, and
the second metal layer includes electrolytic copper.

12. The printed circuit board of claim 1, wherein
the wiring pattern is provided in plural, and
the plurality of wiring patterns have a line L/space S less than 10 μm/10 μm.

13. The printed circuit board of claim 1, wherein
the insulating layer includes first and second insulating layers,
the wiring pattern is disposed on an upper surface of the first insulating layer,
the second insulating layer is disposed on an upper surface of the first insulating layer, and
the second insulating layer covers at least a portion of the wiring pattern.

14. A printed circuit board comprising:
a substrate;
a first metal layer disposed on the substrate;
a second metal layer disposed on the first metal layer; and
a barrier layer disposed to surround the second metal layer and having a protrusion at least partially protruding from a lower end of the barrier layer in a plane direction, perpendicular to a stacking direction.

15. The printed circuit board of claim 14, wherein
the first metal layer is wider than the second metal layer on a cross-section of the plane direction and the stacking direction, and
the protrusion covers a portion of an upper surface of the first metal layer and is spaced apart from a portion of a side surface of the first metal layer.

16. The printed circuit board of claim 14, wherein
the second metal layer is thicker than the first metal layer, and
the first metal layer is thicker than the barrier layer.

17. The printed circuit board of claim 14, wherein the barrier layer includes an inorganic oxide film having a thickness less than 100 nm.

18. The printed circuit board of claim 17, wherein the inorganic oxide film includes at least one of Al₂O₃, TiO₂, ZnO, ZnO₂, ZrO₂, SnO, SnO₂, HfO₂, or SiO₂.
